(19) United States
(12) Patent Application Publication
(10) Pub. No.: US 2025/0287766 A1
(43) Pub. Date: Sep. 11, 2025

(54) LIGHT-EMITTING ELEMENT, LIGHT-EMITTING COMPONENT AND MANUFACTURING METHOD

(71) Applicant: XIAMEN SAN'AN OPTOELECTRONICS CO., LTD., Xiamen (CN)

(72) Inventors: Xueping YE, Xiamen (CN); Te-ling HSIA, Xiamen (CN); Chia-en LEE, Xiamen (CN)

(21) Appl. No.: 19/220,186

(22) Filed: May 28, 2025

Related U.S. Application Data
(63) Continuation of application No. PCT/CN2023/134488, filed on Nov. 27, 2023.

(30) Foreign Application Priority Data
Nov. 29, 2022 (CN) 2022115121018

(51) Int. Cl. H10H 29/85; H10H 29/01; H10H 29/24; H10H 29/80

(52) U.S. Cl. CPC H10H 29/857; H10H 29/034; H10H 29/0364; H10H 29/24; H10H 29/842

(57) ABSTRACT

A light-emitting element, and a light-emitting component and its manufacturing method, belonging to field of semiconductor manufacturing technologies, are provided. The light-emitting element includes at least two light-emitting units adjacent to one another, and a bridging conductive bridge bridged between adjacent light-emitting units to make the adjacent light-emitting units be connected in series. The light-emitting unit includes an epitaxial structure and a dielectric layer. The epitaxial structure includes first and second surfaces. The light-emitting units connected in series are defined with a trench therebetween penetrating from the first surface to the second surface. The second surface is formed with multiple removal areas. The dielectric layer covers the second surfaces of the light-emitting units connected in series and extends across the trench. The bridging conductive bridge is on a side of the dielectric layer facing away from the epitaxial structure and electrically connected to the epitaxial structure through the removal area.

### TECHNICAL FIELD

The disclosure relates to the field of semiconductor manufacturing technologies, and particularly to a light-emitting element, a light-emitting component and a manufacturing method of the light-emitting component.

### BACKGROUND

Micro light emitting diode (LED) display technology refers to a display technology that uses self-luminous LEDs at the micrometer scale as light-emitting pixel units, and assembles them onto a driving panel to form a high-density LED array. Due to characteristics of the Micro LED, such as small chip size, high integration, and self-luminance, it has greater advantages over liquid crystal display (LCD) and organic light-emitting diode (OLED) in terms of brightness, resolution, contrast ratio, power consumption, service life, response speed, and thermal stability.

To meet a demand for LED brightness, high-voltage Micro LED chips have emerged. Microfabrication techniques are used to achieve isolation between adjacent LED cells on an epitaxial layer. Then, through deposition of metal, the LED cell arrays are connected in series, thereby endowing the LED products with better optoelectronic properties and meeting the market's demand for high light power density as much as possible. However, in a manufacturing process of existing high-voltage Micro LED chips, there are problems such as poor manufacturing yield, which leads to insufficient chip performance.

### SUMMARY

A light-emitting element is provided, and the light-emitting element includes at least two light-emitting units adjacent to one another and a bridging conductive bridge. The bridging conductive bridge is bridged between adjacent ones of the at least two light-emitting units to make the adjacent ones of the light-emitting units be connected in series. Each of the at least two light-emitting units includes an epitaxial structure and a dielectric layer. The epitaxial structure includes a first surface and a second surface opposite to each other, the first surface is a light-emitting surface, the adjacent ones of at least two light-emitting units connected in series are defined with a trench therebetween penetrating from the first surface to the second surface, and the second surface includes multiple removal areas not penetrating through the epitaxial structure. The dielectric layer is disposed covering the second surface of one of the light-emitting units and extends across the trench to cover the second surface of the light-emitting unit connected in series with the one of the at least two light-emitting units, the bridging conductive bridge is located on a side of the dielectric layer facing away from the epitaxial structure and is electrically connected to the epitaxial structure through at least one of the multiple removal areas.

By designing the light-emitting elements as described above, the trench configured to divide a series of light-emitting units are set on the light-emitting surface of the epitaxial structure, while the bridging conductive bridges used for series connection of light-emitting units, as well as the removal areas and the dielectric layer, are set on the other surface of the epitaxial structure. This not only allows the bridging conductive bridges to be deposited without crossing over the trench, effectively avoiding disconnection of the bridging conductive bridges, but also eliminates the need for secondary alignment during trench formation, which could otherwise cause operational deviations. Therefore, a yield of the light-emitting element can be effectively improved.

In an embodiment, observed from above the light-emitting element towards the epitaxial structure, projections of the multiple removal areas on the epitaxial structure are located outside a projection of the trench on the epitaxial structure. By staggering a placement of the trench and the multiple removal areas, it is possible to effectively avoid problems such as height differences or coating discontinuities in the bridging conductive bridge. Coating can be performed on the dielectric layer at an equal height, which is conducive to the stability of the light-emitting component manufacturing process and further improves the performance of the light-emitting component.

In an embodiment, the multiple removal areas include a first internal removal area located on an inner side of the epitaxial structure. The first internal removal area is configured to achieve an electrical connection between the epitaxial structure and the bridging conductive bridge. A distance H from the first internal removal area to a bottom of the trench is in a range of 0.5 micrometers (μm) to 3 μm, thereby shortening a bridging distance of the bridging conductive bridge and preventing the distance from being too small and affecting the conductivity of series.

In an embodiment, a thickness of the bridging conductive bridge is in a range of 0.5 μm to 1.5 μm, and a material of the bridging conductive bridge at least includes one of a dielectric material, a metal material, and a semiconductor material.

In an embodiment, the epitaxial structure includes a first type semiconductor layer, a light-emitting layer, and a second type semiconductor layer sequentially stacked along a direction from the first surface to the second surface. The dielectric layer is defined with a first through hole and a second through hole, and the first through hole penetrates through the dielectric layer and is in communication with the first internal removal area. The first internal removal area extends from the second surface toward the first surface to expose the first type semiconductor layer of the one of the light-emitting units. The second through hole penetrates through the dielectric layer and exposes the second type semiconductor layer of the light-emitting unit connected in series with the one of the at least two light-emitting units. The bridging conductive bridge is electrically connected to the first type semiconductor layer and the second type semiconductor layer of two of the at least two light-emitting units connected in the series through the first through hole and the second through hole, respectively.

In an embodiment, a thickness of the dielectric layer is in a range of 0.5 μm to 1.5 μm, and the dielectric layer at least includes a reflective layer. The thickness of the dielectric layer is configured to prevent it from being too thin to provide adequate support, or too thick, which would waste material and complicate the etching process.

In an embodiment, the multiple removal areas further include an external removal area located at outer edges of the epitaxial structure. The external removal area extends from the second surface toward the first surface of the epitaxial structure and exposes the first type semiconductor layer, and the dielectric layer extends to cover the external removal area. Through the above design of covering with the dielectric layer, not only can the light extraction efficiency be improved, but also the structural support of the entire light-emitting element can be enhanced, thereby increasing the stability of the manufacturing process. In addition, the contact area between the bridging conductive bridge and the light-emitting element is increased. During the manufacturing process, defects such as breakage or cracks will not occur, allowing the bridging conductive bridge to be made thinner.

In an embodiment, an opening of the trench gradually decreases along a direction from the first surface towards the second surface, which can effectively reduce the bridging distance of the bridging conductive bridge and thus reduce an overall size of the chip.

In an embodiment, the trench has a sidewall connecting the first surface with the second surface, and the sidewall is formed by at least one plane, at least one curved surface, or a combination of the at least one plane and the at least one curved surface.

In an embodiment, the trench has a top edge at a connection between the sidewall and the first surface, and a bottom edge at a connection between the sidewall and the second surface; and an intersection angle θ between the second surface and a common perpendicular of the top edge and the bottom edge is less than 90°.

In an embodiment, the intersection angle θ is in a range greater than or equal to 45° and less than 70°, or in a range greater than or equal to 70° and less than 80°, or in a range greater than or equal to 80° and less than 90°. By limiting the intersection angle θ as described above, it is possible to effectively avoid the intersection angle θ being too small and affecting the light-emitting area, and too large and affecting the manufacturing process.

In an embodiment, the intersection range of the angle θ is in a range greater than 45° and less than 75°, which is beneficial for covering the insulating layer to protect the epitaxial structure.

In an embodiment, the sidewall is an inclined plane or an inclined curved surface.

In an embodiment, when the sidewall is the inclined curved surface, an intersection angle β between a tangent of the inclined curved surface and the second surface is greater than 30° and less than 90°, and the intersection angle β gradually increases or gradually decreases.

In an embodiment, the sidewall is formed by at least two planes with different incline angles, at least two curved surfaces with different curvature radius, or a combination of the at least two planes and the at least two curved surfaces.

By limiting the sidewall of the trench as described above, the trench is designed with a structure of wider at a top edge and narrower at a bottom edge. The structure helps to reduce the bridging distance of the bridging conductive bridge, ensuring the stability of the bridge connection and preventing defects such as cracks or breaks, thereby enhancing the reliability of the light-emitting component.

In an embodiment, the trench between two of the at least two light-emitting units connected in series has a minimum horizontal spacing is greater than or equal to 0.1 μm and less than or equal to 2 μm. Adopting the minimum horizontal spacing is conducive to the light-emitting performance of the light-emitting element and ensures the stability of the manufacturing process.

In an embodiment, the light-emitting units connected in series of the at least two light-emitting units has a maximum horizontal distance, and the maximum horizontal distance is less than a minimum spacing between adjacent two the light-emitting elements.

In an embodiment, for the light-emitting element constituted by two light-emitting units connected in series of the at least two light-emitting units, a size of long side of the light-emitting element does not exceed 200 μm, and a size of short side of the light-emitting element does not exceed 100 μm. By limiting the sizes of the light-emitting element as described above, the size of the light-emitting component is prevented from being too large, thereby reducing costs.

In an embodiment, a light-emitting component is provided, which includes the multiple light-emitting elements described above, a circuit substrate, and multiple metal electrodes. The multiple light-emitting elements are arranged at intervals on the circuit substrate, and the multiple metal electrodes are disposed between the circuit substrate and at least two light-emitting units of each of the multiple light-emitting elements, and are electrically connected to the circuit substrate and the multiple light-emitting elements. The light-emitting component that adopts the light-emitting element described in the above embodiments not only ensures the deposition effect of the bridging conductive bridge and reduces the bridging distance of the bridging conductive bridge, but also minimizes the damage caused by the removal process, thereby enhancing the stability and reliability of the manufacturing process of the light-emitting component.

A manufacturing method of a light-emitting component includes steps as follows.

An epitaxial structure is formed on a growth substrate, the epitaxial structure includes a first surface and a second surface opposite to each other, and the epitaxial structure includes a first type semiconductor layer, a light-emitting layer, and a second type semiconductor layer sequentially stacked along a direction from the first surface towards the second surface. Portions of outer edges of the epitaxial structure on the second surface of the epitaxial structure are removed to form an external removal area, and a portion of an interior of the epitaxial structure is removed until exposing the first type semiconductor layer to form a first internal removal area. Then a dielectric layer is formed on the second surface and the external removal area, and the dielectric layer extends to cover a sidewall of the first internal removal area.

A portion of the dielectric layer is removed to form a first through hole in communication with the first internal removal area. Another portion of the dielectric layer is removed to form a second through hole. And a bridging conductive bridge is formed on the dielectric layer, and the bridging conductive bridge is electrically contacted with the first type semiconductor layer and the second type semiconductor layer of the epitaxial structure through the first internal removal area, the first through hole, and the second through hole.

An insulating layer is deposited, the insulating layer covers the dielectric layer, the bridging conductive bridge, and the external removal area. Multiple metal electrodes are formed on the insulating layer by evaporation. And the multiple metal electrodes are electrically contacted with the first type semiconductor layer and the second type semiconductor layer of the epitaxial structure. Conductive pads are formed on the multiple metal electrodes and the multiple metal electrodes formed with the conductive pads are then transferred onto a temporary substrate. Subsequently, the growth substrate is removed to expose the first surface of the epitaxial structure.

A portion of the epitaxial structure is removed from the first surface to the second surface to thereby form a trench dividing the epitaxial structure into a series of light-emitting units.

In an embodiment, observed from above the light-emitting component towards the epitaxial structure, projections of the external removal area and the first internal removal area on the epitaxial structure are located outside a projection of the trench on the epitaxial structure.

Other features and beneficial effects of the disclosure will be described in the following specification, and in part will become apparent from the specification, or may be learned by practicing the disclosure.

### BRIEF DESCRIPTION OF DRAWINGS

In order to provide a clearer explanation of the embodiments of the disclosure or the technical solutions in the related art, a brief introduction will be given to the attached drawings required for the description of the embodiments or the prior art. It is apparent that the attached drawings described below are some embodiments of the disclosure. For those skilled in the art, other drawings can be obtained based on the attached drawings without creative labor.

FIG. 1 illustrates a schematic cross-sectional structural view of a light-emitting component according to an embodiment of the disclosure.

FIG. 2 illustrates a schematic top view of the light-emitting component according to an embodiment of the disclosure.

FIG. 3 illustrates a schematic cross-sectional view of a partial structure of a light-emitting element according to an embodiment of the disclosure.

FIG. 4 through FIG. 8 illustrate schematic cross-sectional structural views of light-emitting components according to other embodiments of the disclosure.

FIG. 9 through FIG. 13 illustrate schematic structural views in a manufacturing method of a light-emitting component according to an embodiment of the disclosure.

### DESCRIPTION OF REFERENCE NUMERALS

1—circuit substrate; 2—light—emitting element; 3—bridging conductive bridge; 4—conductive pad; 5—metal electrode; 21—epitaxial structure; 22—dielectric layer; 211—first type semiconductor layer; 212—light—emitting layer; 213—second type semiconductor layer; 23—insulating layer; 6—removal areas; 61—first internal removal area; 62—second internal removal area; 63—external removal area; 21a—first through hole; 21b—second through hole; 24—trench; 24a—sidewall; 24b—top edge; 42—bottom edge; 7—growth substrate; 8—temporary substrate; D1—maximum horizontal distance; D2—minimum horizontal spacing.

### DETAILED DESCRIPTION OF EMBODIMENTS

In order to clarify the purpose, technical solution, and advantages of the embodiments of the disclosure, the following will provide a clear and complete description of the technical solution in the embodiments of the disclosure in conjunction with the attached drawings. The technical features designed in different embodiments of the disclosure described below can be combined with each other as long as they do not conflict with each other.

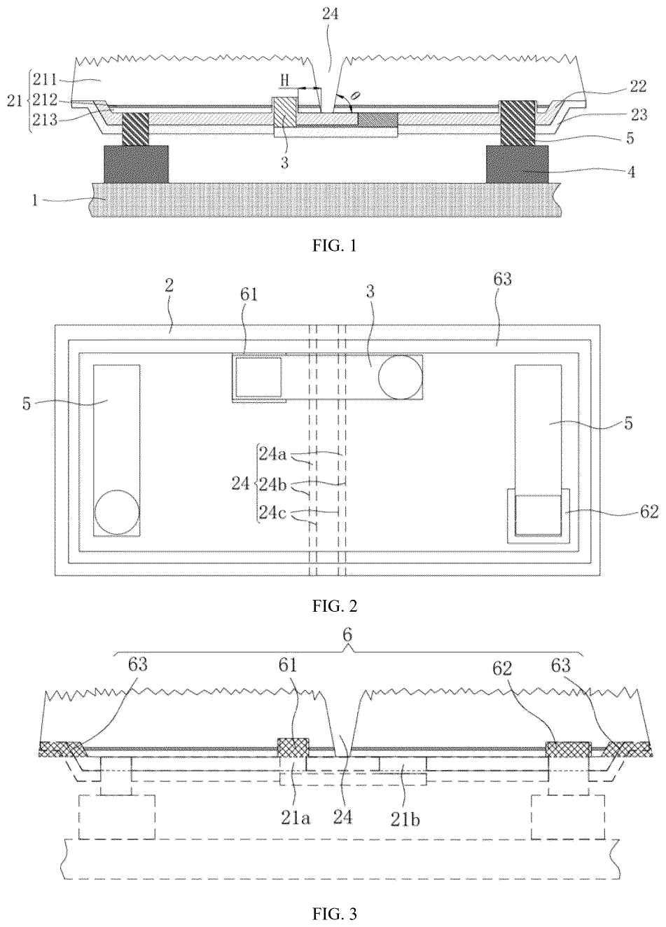

As shown in FIG. 1, which illustrates a schematic cross-sectional structural view of a light-emitting component. To achieve at least one of the advantages mentioned above or other advantages, an embodiment of the disclosure provides a light-emitting element 2, which includes at least two light-emitting units adjacent to one another and a bridging conductive bridge 3.

The bridging conductive bridge 3 is bridged between adjacent ones of the at least two light-emitting units to make the adjacent ones of the light-emitting units be connected in series. A thickness of the bridging conductive bridge 3 is in a range of 0.5 μm to 1.5 μm to ensure effective series connection of the multiple light-emitting units. A material of the bridging conductive bridge 3 includes one of a dielectric material, a metal material, and a semiconductor material. In this embodiment, a metal material is selected.

As shown in FIG. 1, the light-emitting element 2 specifically includes two adjacent light-emitting units, which are connected in a series by a single bridging conductive bridge 3. It should be noted that the light-emitting element 2 is not limited to the two light-emitting units shown in FIG. 1. Those skilled in the art can set the number according to actual working requirements. In addition, a connection relationship between light-emitting units is not limited to series connection, and can also be set to parallel connection or a combination of series and parallel connections according to actual working requirements. Specifically, in the light-emitting element 2 constituted by two light-emitting units connected in series, the light-emitting element 2 is generally rectangular or quasi-rectangular. A size of long side of the light-emitting element 2 does not exceed 200 μm, and a size of short side of the light-emitting element 2 does not exceed 100 μm. By limiting the sizes of the light-emitting element 2 as described above, the performance of the light-emitting element can be ensured while avoiding an overly large size, thereby reducing production costs.

Each light-emitting unit includes at least an epitaxial structure 21 and a dielectric layer 22. The epitaxial structure 21 includes a first surface and a second surface that are opposite to each other, and the first surface is a light-emitting surface. Specifically, the epitaxial structure 21 includes a first type semiconductor layer 211, a light-emitting layer 212, and a second type semiconductor layer 213 that are sequentially stacked along a direction from the first surface to the second surface.

The first type semiconductor layer 211 can be composed of III-V or II-VI compound semiconductors and can be doped with a first dopant. The first type semiconductor layer 211 can be composed of semiconductor materials with the chemical formula In_{X1}Al_{Y1}Ga_{1-X1-Y1}N (where 0≤X1≤1, 0≤Y1≤1, and 0≤X1+Y1≤1), such as gallium nitride (GaN), aluminum gallium nitride (AlGaN), indium gallium nitride (InGaN) and indium aluminum gallium nitride (InAlGaN), or materials selected from aluminum gallium arsenide (AlGaAs), gallium phosphide (GaP), gallium arsenide (GaAs), gallium aridesen phosphide aluminum gallium indium phosphide (GaAsP), and (AlGaInP). Additionally, the first dopant can be an n-type dopant, such as silicon (Si), germanium (Ge), tin (Sn), selenium (Se), and tellurium (Te). When the first dopant is an n-type dopant, the first type semiconductor layer 211 doped with the first dopant is an n-type semiconductor layer. The first dopant can also be a p-type dopant, such as magnesium (Mg), zinc (Zn), calcium (Ca), strontium (Sr), and barium (Ba), in which case the first type semiconductor layer 211 doped with the first dopant is a p-type semiconductor layer. The first surface of the first type semiconductor layer 211 is the light-emitting surface. To enhance the light extraction efficiency of the light-emitting element 2, the first surface of the first type semiconductor layer 211 can be roughened to form a roughened structure. In some optional embodiments, the first surface may not be roughened.

The light-emitting layer 212 is disposed between the first type semiconductor layer 211 and the second type semiconductor layer 213. The light-emitting layer 212 is a region that provides light radiation through the recombination of electrons and holes. Depending on the desired emission wavelength, different materials can be selected for the light-emitting layer 212. By adjusting a compositional ratio of the semiconductor material in the light-emitting layer 212, it is possible to achieve light emission at different wavelengths. The light-emitting layer 212 can be a single quantum well or a periodic structure of multiple quantum wells. The light-emitting layer 212 includes well layers and barrier layers, and the barrier layers include a larger bandgap than the well layers. To enhance the light emission efficiency of the light-emitting layer 212, this can be achieved by modifying the material of the quantum wells, the number of paired quantum wells and quantum barriers, their thicknesses, and/or other characteristics within the light-emitting layer 212.

The second type semiconductor layer 213 is formed on the light-emitting layer 212 and can be composed of III-V or II-VI compound semiconductors. The second type semiconductor layer 213 can be doped with a second dopant. The second type semiconductor layer 213 can be composed of semiconductor materials with the chemical formula In_{X2}Al_{Y2}Ga_{1-X2-Y2}N (where 0≤X2≤1, 0≤Y2≤1, and 0≤X2+Y2≤1), or materials selected from AlGaAs, GaP, GaAs, GaAsP, and AlGaInP. When the second dopant is a p-type dopant, such as Mg, Zn, Ca, Sr, and Ba, the second type semiconductor layer 213 doped with the second dopant is a p-type semiconductor layer. The second dopant can also be an n-type dopant, such as Si, Ge, Sn, Se, and Te. When the second dopant is an n-type dopant, the second type semiconductor layer 213 doped with the second dopant is an n-type semiconductor layer. When the first type semiconductor layer 211 is an n-type semiconductor layer, the second type semiconductor layer 213 is a p-type semiconductor layer. Conversely, when the first type semiconductor layer 211 is a p-type semiconductor layer, the second type semiconductor layer 213 is an n-type semiconductor layer.

The epitaxial structure 21 may also include other material layers, such as a current spreading layer, a window layer, or an ohmic contact layer, which can be configured as different multiple layers based on different doping concentrations or compositional contents. In this embodiment, the material of the epitaxial structure 21 is preferably based on GaN, with the light-emitting layer 212 emitting blue light.

The dielectric layer 22 is configured to support the entire light-emitting unit and can be made of insulating materials. specifically, a thickness of the dielectric layer 22 is in a range of 0.5 μm to 1.5 μm to prevent it from being too thin to provide adequate support, or too thick, which would waste material and complicate the etching process. To enhance the light-emitting efficiency, the dielectric layer 22 can at least include a reflective layer, specifically a distributed bragg reflector (DBR), but not limited to this. It includes alternately stacked first and second layers, and a refractive index of the first layer is different from that of the second layer. The materials for the first and second layers include dielectric oxides containing titanium oxide (TiO), silicon oxide (SiO), or aluminum oxide (AlO). The reflective layer can also be an omnidirectional reflector (ODR), which includes combining metallic materials such as Al, silver (Ag), gold (Au) with the DBR to form an omnidirectional reflector. Certainly, in addition to the reflective layer, the dielectric layer 22 can also include structures such as a current spreading layer and a transparent conductive layer to enhance the performance of the entire light-emitting element.

In traditional high-voltage Micro LED chips, when using LED single cells to bridge the bridging conductive bridges for series connection, a miniature electrostatic accelerometer (MESA) photolithography structure, the bridging conductive bridge, and an isolation etch (ISO) etching are generally designed on the same chip surface. This can lead to poor deposition of the bridging conductive bridge at the ISO etching location, making it prone to metal deposition discontinuities. Moreover, during the manufacturing process, secondary alignment is required on the MESA photolithography structure during ISO etching, which can introduce operational deviations and inaccuracies, thereby affecting the performance of the LED chip.

In the embodiment, as shown in FIG. 1, to effectively address the above problems, the light-emitting units connected in series are defined with a trench 24 therebetween that penetrates from the first surface to the second surface. The trench 24 is set on the side of the first surface and divides the light-emitting element 2 into a series of light-emitting units. Specifically, the trench 24 can be obtained by the ISO etching. A shape and a structure of the trench 24 can be designed according to actual requirements and are not limited here.

In the embodiment, as shown in FIG. 3, the second surface includes several removal areas 6 that do not penetrate through the epitaxial structure 21. The dielectric layer 22 is disposed covering the second surface of one of the light-emitting units and extends across the trench 24 to cover the second surface of the light-emitting unit connected in series with the one of the light-emitting units. The bridging conductive bridge 3 is located on a side of the dielectric layer 22 facing away from the epitaxial structure 21 and is electrically connected to the epitaxial structure 21 through at least one of the several removal area 6.

By setting the trench 24, which is used to divide the light-emitting element 2 into a series of light-emitting units, on the light-emitting surface of the epitaxial structure 21, and placing the bridging conductive bridge 3, the removal areas 6, and the dielectric layer 22, which are used for the series connection of light-emitting units, on an opposite side of the light-emitting surface, not only is the bridging conductive bridge 3 prevented from having to be deposited across the trench 24, effectively avoiding disconnection of the bridging conductive bridge 3, but also secondary alignment during a formation of the trench 24, which could cause operational deviations, is eliminated. This effectively improves the yield of the light-emitting elements. Moreover, by placing the dielectric layer 22 between the epitaxial structure 21 and the bridging conductive bridge 3, the structural support of the entire light-emitting element 2 is enhanced, the stability of the manufacturing process is improved, and the contact area between the bridging conductive bridge 3 and the light-emitting element 2 is increased. This ensures that the bridging conductive bridge 3 will not experience defects such as breakage or cracks during the manufacturing process.

In some specific embodiments, as shown in FIGS. 2 and 3, observed from above the light-emitting element 2 towards the epitaxial structure 21, projections of the removal areas 6 on the epitaxial structure 21 are located outside a projection of the trench 24 on the epitaxial structure 21. That is, the positions of the removal areas 6 and the trench 24 are staggered. During the removal process, removal can be performed at different locations respectively. This design effectively avoids the problems encountered in traditional removal processes, such as poor process stability, increased damage to the light-emitting component, height differences in the bridging conductive bridge 3, or coating discontinuities, which arise when these two features are located in the same overlapping position. Coating can be performed on the dielectric layer 22 at an equal height, which is conducive to improving the transfer yield of the light-emitting element 2 and further enhancing the performance of the light-emitting component.

The removal areas 6 includes a first internal removal area 61 located on an inner side of the epitaxial structure 21. The first internal removal area 61 is configured to achieve an electrical connection between the epitaxial structure 21 and the bridging conductive bridge 3. As shown in FIG. 1, a distance H from the first internal removal area 61 to a bottom of the trench 24 is in a range of 0.5 μm to 3 μm. This further shortens the bridging distance of the bridging conductive bridge 3 while avoiding difficulties in the fabrication of the removal areas 6 due to an excessively short bridging distance. However, the embodiments of this disclosure are not limited to this range.

Furthermore, the series connection between the light-emitting units and the bridging conductive bridge 3 is achieved as follows: The dielectric layer 22 is defined with a first through hole 21a and a second through hole 21b. The first through hole 21a penetrates through the dielectric layer 22 and communicates with the first internal removal area 61. The first internal removal area 61 extends from the second surface toward the first surface to expose the first type semiconductor layer 211 of the one of the light-emitting units. The second through hole 21b penetrates through the dielectric layer 22 and exposes the second type semiconductor layer 213 the light-emitting unit connected in series with the one of the light-emitting units. The bridging conductive bridge 3 is electrically connected to the first type semiconductor layer 211 and the second type semiconductor layer 213 of the two light-emitting units connected in the series through the first through hole 21a and the second through hole 21b, respectively.

In addition, to protect and insulate the light-emitting element 2 and prevent foreign matter from entering the light-emitting element 2, the light-emitting element 2 further includes an insulating layer 23, which covers the dielectric layer 22 and the bridging conductive bridge 3. Specifically, a material of the insulating layer 23 can be a non-conductive material, selected from the group of inorganic oxides and nitrides, more specifically, silicon dioxide, silicon nitride, titanium oxide, tantalum oxide, niobium oxide, barium titanate, magnesium fluoride, and aluminum oxide.

In an embodiment, to further protect the light-emitting element 2 and enhance the light extraction efficiency, the removal areas 6 also include an external removal area 63 located at outer edges of the epitaxial structure 21. The external removal area 63 extends from the second surface toward the first surface of the epitaxial structure 21 and exposes the first type semiconductor layer 211. The dielectric layer 22 and the insulating layer 23 extend to cover the external removal area 63. This design not only further improves the light extraction efficiency but also enhances the structural support of the entire light-emitting element 2.

In an embodiment, an opening of the trench 24 gradually decreases along a direction from the first surface towards the second surface. This design gives the trench 24 a structure that is wider at the top edge and narrower at the bottom edge. The narrower bottom edge is used for the bridging of the bridging conductive bridge 3, effectively reducing the bridging distance of the bridging conductive bridge 3. This not only reduces the overall chip size and enhances light-emitting efficiency but also allows for a thinner bridging conductive bridge 3, lowering production costs while ensuring the stability of the bridge connection. It reduces the likelihood of defects such as cracks or breaks, thereby improving the reliability of the light-emitting component.

In an embodiment, the trench 24 has a sidewall 24a connecting the first surface with the second surface, and the sidewall 24a is formed by at least one plane, at least one curved surface, or a combination of the at least one plane and the at least one curved surface.

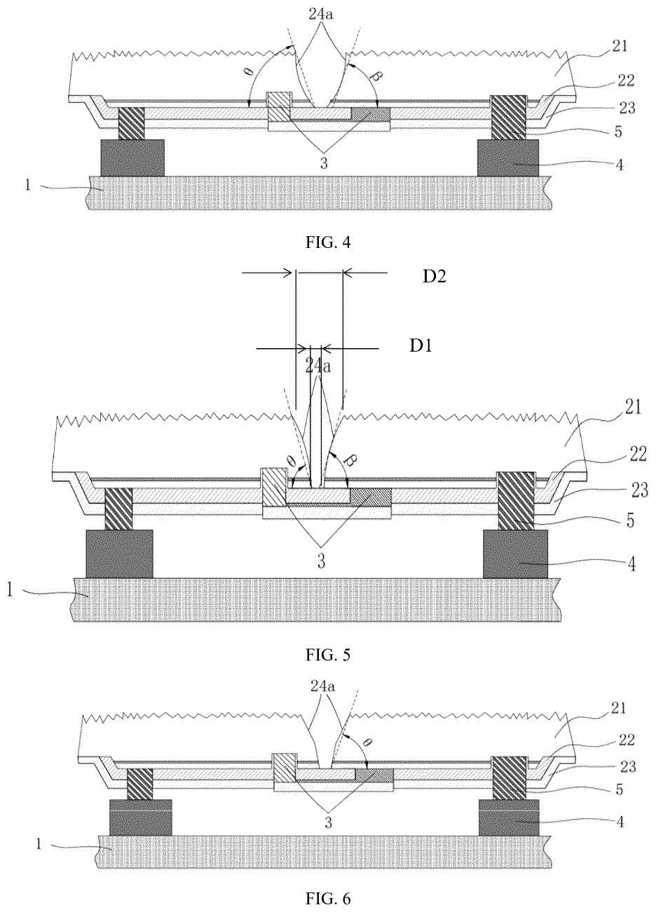

Specifically, as shown in FIGS. 1, 4, and 5, the sidewall 24a of the trench 24 can be an inclined plane or an inclined curved surface, that is, its cross-sectional shape is trapezoidal with the top wider than the bottom. When the sidewall 24a is an inclined curved surface, the angle β between a tangent of the inclined curved surface and the second surface is greater than 30° and less than 90°. The angle β can gradually decrease from the first surface towards the second surface to form a concave arc as shown in FIG. 4, or it can gradually increase from the first surface towards the second surface to form a convex arc as shown in FIG. 5. Compared to the concave design in FIG. 4, the convex arc design in FIG. 5 can better protect the first internal removal area 61 from excessive exposure or even breakdown of the epitaxial structure 21 during the manufacturing process.

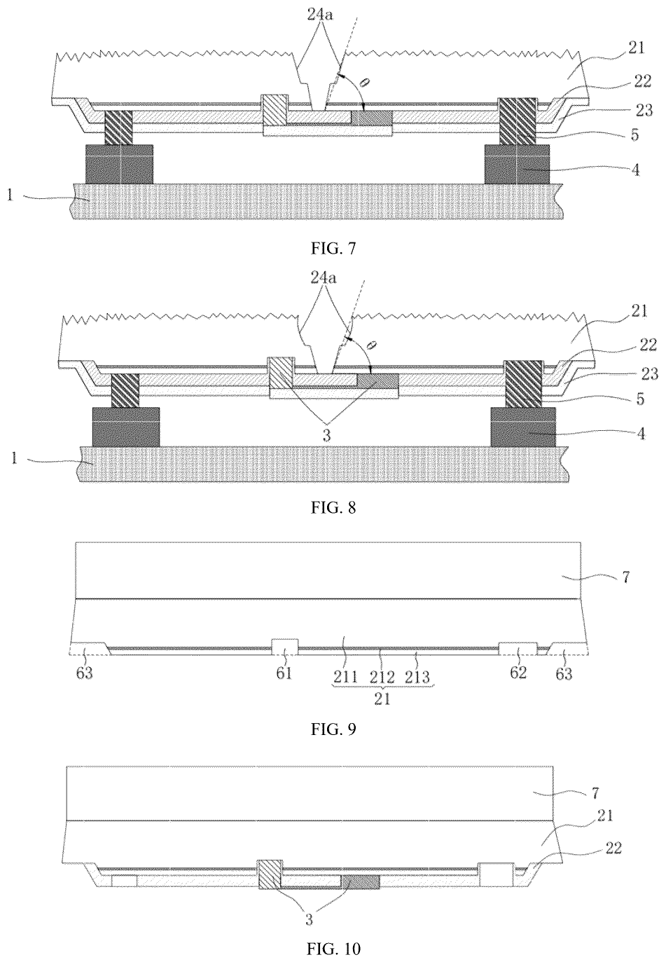

The sidewalls 24a is formed by at least two planes with different incline angles, at least two curved surfaces with different curvature radius, or a combination of the at least two planes and the at least two curved surfaces. For example, as shown in FIG. 6, the sidewall 24a is composed of two planes with different inclination angles. As shown in FIG. 7, the sidewall 24a of the trench can include a first inclined plane, a horizontal plane, and a second inclined plane that extend sequentially from the first surface towards the second surface, forming a stepped structure. This can reduce the step difference during fabrication and is conducive to the stability of the processing. To facilitate the processing of the sidewall 24a, the inclination angle of the first inclined plane is less than or equal to the inclination angle between the inclined plane and the second surface.

Certainly, a configuration of the sidewall 24a is not limited to the examples shown in the attached drawings. Based on the concept, those skilled in the art can replace it with other combinations, and it can also be composed of three or four different planes and curved surfaces, as shown in FIG. 8. The specific configuration is set according to actual requirements, and all such replacements fall within the scope of protection of the disclosure.

In another specific embodiment, the trench 24 has a top edge 24b at a connection between the sidewall 24a and the first surface, and a bottom edge 24c at a connection between the sidewall 24a and the second surface. The intersection angle θ between the second surface and a common perpendicular of the top edge 24b and the bottom edge 24c is less than 90°. It should be noted that, in the manufacturing process, the top edge 24b and the bottom edge 24c of the trench 24 may not be perfectly parallel in space due to design or manufacturing tolerances. Therefore, if the top edge 24b and the bottom edge 24c are parallel lines, the intersection angle between the plane formed by these edges (i.e., the plane containing the common perpendicular line) and the second surface can be defined as θ. If the top edge 24b and the bottom edge 24c are skew lines, the intersection angle between the second surface and the common perpendicular line of the top edge 24b and the bottom edge 24c is defined as θ. By specifying that the intersection angle θ is less than 90°, it can be ensured that, regardless of how the sidewall 24a change, the bottom area of the trench 24 is smaller than the top area. This facilitates the effective deposition of the dielectric layer 22 and the bridging conductive bridge 3 at the bottom of the trench 24. It not only enhances the connection stability of the bridging conductive bridge 3 but also allows the bridge to be made thinner, thereby reducing the manufacturing cost of the light-emitting component.

In an embodiment, the intersection angle θ is in a range greater than or equal to 45° and less than 70°, or in a range greater than or equal to 70° and less than 80°, or in a range greater than or equal to 80° and less than 90°. By limiting the range of the intersection angle θ as described above, it is possible to effectively avoid the intersection angle θ being too small, which could affect the light-emitting area, or too large, which could affect the manufacturing process. Furthermore, the intersection angle θ is in a range greater than 45° and less than 75°. This range of the intersection angle θ facilitates the deposition of the insulating layer 23 on a backside of the light-emitting component, thereby effectively protecting the epitaxial structure 21 and the light-emitting layer 212.

In an embodiment, the trench 24 between two of the two light-emitting units connected in series has a minimum horizontal spacing D2 greater than or equal to 0.1 μm and less than or equal to 2 μm. Adopting this spacing range is conducive to the light-emitting performance of the light-emitting element 2 and ensures the stability of the manufacturing process. In another embodiment, the light-emitting units connected in series of the two light-emitting units has a maximum horizontal distance D1, and the maximum horizontal distance D1 is less than a minimum spacing between adjacent two the light-emitting elements 2.

As shown in FIG. 1, the light-emitting component includes multiple light-emitting elements 2 described above, a circuit substrate 1, and multiple metal electrodes 5.

The multiple light-emitting elements 2 are arranged at intervals on the circuit substrate 1. The circuit substrate 1 can be a complementary metal-oxide-semiconductor (CMOS) substrate, a liquid crystal on silicon (LCOS) substrate, a thin film transistor (TFT) substrate, or any other substrate with working circuits to drive the multiple light-emitting elements 2 to emit light of corresponding colors. There is no limitation to these options.

The metal electrodes 5 are disposed between the circuit substrate 1 and the two light-emitting units of each of the multiple light-emitting elements, and are electrically connected to the circuit substrate 1 and the multiple light-emitting elements 2. The metal electrodes 5 can be single-layer, double-layer, or multi-layer structures, such as Ti/Al, Ti/Al/Ti/Au, Ti/Al/Ni/Au, V/Al/Pt/Au, and other multilayer structures. In an optional embodiment, the light-emitting component further includes conductive pads 4, which are in direct contact with the circuit substrate 1 and the metal electrodes 5 to achieve the electrical connection between the light-emitting elements 2 and the circuit substrate 1.

In an embodiment, the removal areas 6 also include a second internal removal area 62 located on the inner side of the epitaxial structure 21. The second internal removal area 62 is configured to achieve the electrical connection between the epitaxial structure 21 and the metal electrodes 5. Specifically, the insulating layer 23 and the dielectric layer 22 define a through hole corresponding to and in communication with the second internal removal area 62. The metal electrodes 5 are electrically connected to the epitaxial structure 21 through the through hole and the second internal removal area 62.

It should be noted that two light-emitting units connected in series can be divided into a first light-emitting unit and a second light-emitting unit. The specific electrical connection method is as follows: an end of the bridging conductive bridge 3 is connected to the first type semiconductor layer 211 of the first light-emitting unit, and another end of the bridging conductive bridge 3 is connected to the second type semiconductor layer 213 of the second light-emitting unit. At least one metal electrode 5 is connected to the second type semiconductor layer 213 of the first light-emitting unit, and at least one other metal electrode 5 is connected to the first type semiconductor layer 211 of the second light-emitting unit. The at least one metal electrode 5 and the at least one other metal electrode 5 are electrically connected to the circuit substrate 1, thereby forming a complete series circuit between the first light-emitting unit and the second light-emitting unit connected in series.

As shown in FIGS. 9 to 13, which illustrate schematic structural views in a manufacturing method of a light-emitting component, a manufacturing method of the light-emitting component are described in details as follows.

As shown in FIG. 9, an epitaxial structure 21 is formed on a growth substrate 7, the epitaxial structure 21 includes a first surface and a second surface opposite to each other, and the epitaxial structure 21 includes a first type semiconductor layer 211, a light-emitting layer 212, and a second type semiconductor layer 213 sequentially stacked along a direction from the first surface to the second surface. The growth substrate 7 can be an insulating substrate or a conductive substrate, and the epitaxial structure 21 can be formed on the growth substrate 7 by methods such as physical vapor deposition (PVD), chemical vapor deposition (CVD), and epitaxial growth. Then, portions of outer edges of the epitaxial structure 21 on the second surface of the epitaxial structure 21 are removed to form an external removal area 63, and a portion of an interior of the epitaxial structure 21 is removed until exposing the first type semiconductor layer 211 to form a first internal removal area 61. Subsequently, a dielectric layer 22 is formed on the second surface and the external removal area 63, and the dielectric layer extends to cover a sidewall of the first internal removal area 61. In this embodiment, the dielectric layer 22 is back-coated on the light-emitting element 2. The dielectric layer 22 can be formed by methods such as vacuum evaporation, sputtering, or CVD. The dielectric layer 22 in the embodiment at least includes a reflective layer, preferably a DBR.

As shown in FIG. 10, a portion of the dielectric layer 22 is removed to form a first through hole 21a in communication with the first internal removal area 61. Another portion of the dielectric layer 22 is removed to form a second through hole 21b. And a bridging conductive bridge 3 is formed on the dielectric layer 22, and the bridging conductive bridge 3 is electrically contacted with the first type semiconductor layer 211 and the second type semiconductor layer 213 of the epitaxial structure 21 through the first internal removal area 61, the first through hole 21a, and the second through hole 21b.

As shown in FIG. 11, an insulating layer 23 is deposited. The insulating layer 23 covers the dielectric layer 22, the bridging conductive bridge 3, and the external removal area 63. The insulating layer 23 is preferably made of SiₓN or SiO₂ material. A portion of the insulating layer 23 and a portion of the dielectric layer 22 are removed to form a through hole. Then, a portion of the epitaxial structure 21 is further removed to expose the first type semiconductor layer 211, thereby forming a second internal removal area 62.

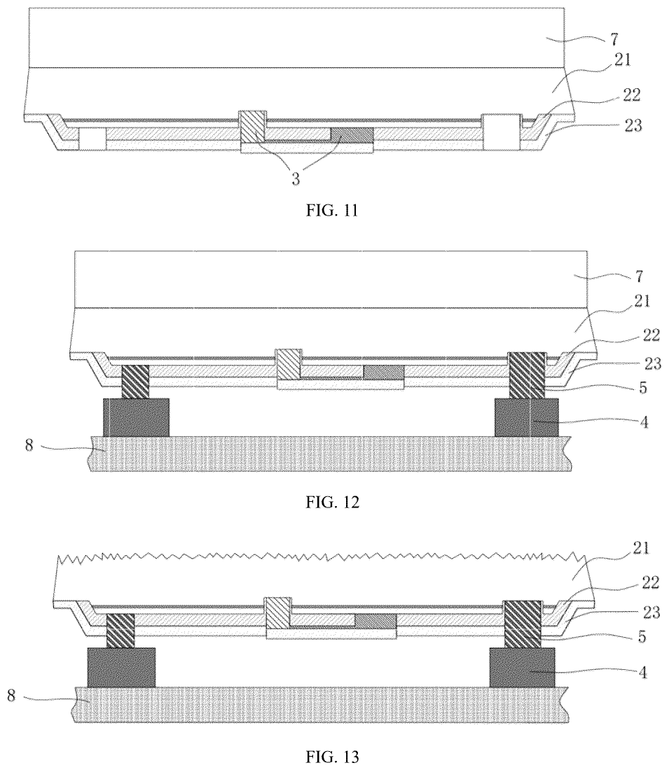

As shown in FIG. 12, multiple metal electrodes 5 are formed on the insulating layer 23 by evaporation, and the multiple metal electrodes 5 are electrically contacted with the first type semiconductor layer 211 and the second type semiconductor layer 213 of the epitaxial structure 21 through the through hole and the second internal removal area 62. Conductive pads 4 are then formed on the multiple metal electrodes 5, and then the metal electrodes 5 formed with the conductive pads 4 are transferred to a temporary substrate 8. Subsequently, as shown in FIG. 13, the growth substrate 7 is removed to expose the first surface of the epitaxial structure 21. In this embodiment, the first surface may be roughened.

Finally, a portion of the epitaxial structure 21 is removed from the first surface to the second surface to thereby form a trench 24. The trench 24 divides the epitaxial structure 21 into a series of light-emitting units, as specifically shown in FIG. 1. A specific structure of the trench 24 can be referred to the embodiments of the light-emitting element described above, and will not be further elaborated here.

In an embodiment, the removal process is selected from at least one of laser ablation, dry etching, and wet etching. The specific method can be chosen according to actual requirements, and no limitation is made herein. The ISO etching process is selected in this embodiment.

In a specific embodiment, observed from above the light-emitting component towards the epitaxial structure 21, projections of the external removal area 63, the first internal removal area 61, and the second internal removal area 62 on the epitaxial structure 21 are located outside a projection of the trench 24 on the epitaxial structure 21. By staggering the positions of the external removal area 63, the first internal removal area 61, and the second internal removal area 62 from the trench 24, it is possible to effectively avoid the defects encountered in traditional removal processes and improve the transfer yield of the light-emitting elements.

In an embodiment, the light-emitting element described in any of the above embodiments, the light-emitting component described in any of the above embodiments, or the manufacturing method of the light-emitting component described in any of the above embodiments is applied to a display device, which can effectively improve the performance of the display device.

It should be finally noted that: the above embodiments are only used to illustrate the technical solution of the disclosure and are not intended to limit it. Although the disclosure has been described in detail with reference to the above embodiments, those skill in the art should understand that they can still modify the technical solutions described in the above embodiments, or replace some or all of the technical features with equivalent ones. These modifications or replacements will not cause the essence of the corresponding technical solutions to depart from the scope of the technical solutions of the disclosure as described in the various embodiments.

What is claimed is:

1. A light-emitting element, comprising:
at least two light-emitting units adjacent to one another;
a bridging conductive bridge, bridged between adjacent ones of the at least two light-emitting units to make the adjacent ones of the light-emitting units be connected in series;
wherein each of the at least two light-emitting units comprises an epitaxial structure and a dielectric layer;
wherein the epitaxial structure comprises a first surface and a second surface opposite to each other, the first surface is a light-emitting surface, the adjacent ones of at least two light-emitting units connected in series are defined with a trench therebetween penetrating from the first surface to the second surface, and the second surface comprises a plurality of removal areas not penetrating through the epitaxial structure;
wherein the dielectric layer is disposed covering the second surface of one of the at least two light-emitting units and extends across the trench to cover the second surface of the light-emitting unit connected in series with the one of the at least two light-emitting units, the bridging conductive bridge is located on a side of the dielectric layer facing away from the epitaxial structure and is electrically connected to the epitaxial structure through at least one of the plurality of removal areas.

2. The light-emitting element as claimed in claim 1, wherein observed from above the light-emitting element towards the epitaxial structure, projections of the plurality of removal areas on the epitaxial structure are located outside a projection of the trench on the epitaxial structure.

3. The light-emitting element as claimed in claim 1, wherein the plurality of removal areas comprise a first internal removal area located on an inner side of the epitaxial structure, the first internal removal area is configured to achieve an electrical connection between the epitaxial structure and the bridging conductive bridge, and a distance H from the first internal removal area to a bottom of the trench is in a range of 0.5 micrometers (μm) to 3 μm.

4. The light-emitting element as claimed in claim 1, wherein a thickness of the bridging conductive bridge is in a range of 0.5 μm to 1.5 μm, and a material of the bridging conductive bridge at least comprises one of a dielectric material, a metal material, and a semiconductor material.

5. The light-emitting element as claimed in claim 3, wherein the epitaxial structure comprises a first type semiconductor layer, a light-emitting layer, and a second type semiconductor layer sequentially stacked along a direction from the first surface to the second surface; the dielectric layer is defined with a first through hole and a second through hole, and the first through hole penetrates through the dielectric layer and is in communication with the first internal removal area; the first internal removal area extends from the second surface toward the first surface to expose the first type semiconductor layer of the one of the at least two light-emitting units; the second through hole penetrates through the dielectric layer and exposes the second type semiconductor layer of the light-emitting unit connected in series with the one of the at least two light-emitting units;
wherein the bridging conductive bridge is electrically connected to the first type semiconductor layer and the second type semiconductor layer of two of the at least two light-emitting units connected in the series through the first through hole and the second through hole, respectively.

6. The light-emitting element as claimed in claim 1, wherein a thickness of the dielectric layer is in a range of 0.5 μm to 1.5 μm, and the dielectric layer at least comprises a reflective layer.

7. The light-emitting element as claimed in claim 5, wherein the plurality of removal areas further comprise an external removal area located at outer edges of the epitaxial structure, the external removal area extends from the second surface toward the first surface of the epitaxial structure and exposes the first type semiconductor layer, and the dielectric layer extends to cover the external removal area.

8. The light-emitting element as claimed in claim 1, wherein an opening of the trench gradually decreases along a direction from the first surface towards the second surface.

9. The light-emitting element as claimed in claim 1, wherein the trench has a sidewall connecting the first surface with the second surface, and the sidewall is formed by at least one plane, at least one curved surface, or a combination of the at least one plane and the at least one curved surface.

10. The light-emitting element as claimed in claim 9, wherein the trench has a top edge at a connection between the sidewall and the first surface, and a bottom edge at a connection between the sidewall and the second surface; and an intersection angle θ between the second surface and a common perpendicular of the top edge and the bottom edge is less than 90°.

11. The light-emitting element as claimed in claim 10, wherein the intersection angle θ is in a range greater than or equal to 45° and less than 70°, or in a range greater than or equal to 70° and less than 80°, or in a range greater than or equal to 80° and less than 90°.

12. The light-emitting element as claimed in claim 10, wherein the intersection angle θ is in a range greater than 45° and less than 75°.

13. The light-emitting element as claimed in claim 9, wherein the sidewall is an inclined plane or an inclined curved surface.

14. The light-emitting element as claimed in claim 13, wherein when the sidewall is the inclined curved surface, an intersection angle β between a tangent of the inclined curved surface and the second surface is greater than 30° and less than 90°, and the intersection angle β gradually increases or gradually decreases.

15. The light-emitting element as claimed in claim 9, wherein the sidewall is formed by at least two planes with different incline angles, at least two curved surfaces with different curvature radius, or a combination of the at least two planes and the at least two curved surfaces.

16. The light-emitting element as claimed in claim 1, wherein the trench between two of the at least two light-emitting units connected in series has a minimum horizontal spacing greater than or equal to 0.1 μm and less than or equal to 2 μm.

17. The light-emitting element as claimed in claim 1, wherein the light-emitting units connected in series of the at least two light-emitting units has a maximum horizontal distance, and the maximum horizontal distance is less than a minimum spacing between adjacent two the light-emitting elements.

18. The light-emitting element as claimed in claim 1, wherein for the light-emitting element constituted by two light-emitting units connected in series of the at least two light-emitting units, a size of long side of the light-emitting element does not exceed 200 μm, and a size of short side of the light-emitting element does not exceed 100 μm.

19. A light-emitting component, comprising:
a plurality of the light-emitting elements as claimed in claim 1;
a circuit substrate, wherein the plurality of light-emitting elements are arranged at intervals on the circuit substrate;
a plurality of metal electrodes, wherein the plurality of metal electrodes are disposed between the circuit substrate and the at least two light-emitting units of each of the plurality of light-emitting elements, and are electrically connected to the circuit substrate and the plurality of light-emitting elements.

20. A manufacturing method of a light-emitting component, comprising:
forming an epitaxial structure on a growth substrate, wherein the epitaxial structure comprises a first surface and a second surface opposite to each other, and the epitaxial structure comprises a first type semiconductor layer, a light-emitting layer, and a second type semiconductor layer sequentially stacked along a direction from the first surface towards the second surface; removing portions of outer edges of the epitaxial structure on the second surface of the epitaxial structure to form an external removal area, and removing a portion of an interior of the epitaxial structure until exposing the first type semiconductor layer to form a first internal removal area; and then forming a dielectric layer on the second surface and the external removal area and extending to cover a sidewall of the first internal removal area;
removing a portion of the dielectric layer to form a first through hole in communication with the first internal removal area; removing another portion of the dielectric layer to form a second through hole; and forming a bridging conductive bridge on the dielectric layer, wherein the bridging conductive bridge is electrically contacted with the first type semiconductor layer and the second type semiconductor layer of the epitaxial structure through the first internal removal area, the first through hole, and the second through hole;
depositing an insulating layer, wherein the insulating layer covers the dielectric layer, the bridging conductive bridge, and the external removal area; forming a plurality of metal electrodes on the insulating layer by evaporation, wherein the plurality of metal electrodes are electrically contacted with the first type semiconductor layer and the second type semiconductor layer of the epitaxial structure; forming conductive pads on the plurality of metal electrodes and then transferring onto a temporary substrate; subsequently, removing the growth substrate to expose the first surface of the epitaxial structure; and
removing a portion of the epitaxial structure from the first surface to the second surface to thereby form a trench dividing the epitaxial structure into a series of light-emitting units;
wherein observed from above the light-emitting component towards the epitaxial structure, projections of the external removal area and the first internal removal area on the epitaxial structure are located outside a projection of the trench on the epitaxial structure.
